(19) United States
(12) Patent Application Publication
(10) Pub. No.: US 2026/0096023 A1
(43) Pub. Date: Apr. 2, 2026

(54) PACKAGE SUBSTRATE AND SEMICONDUCTOR PACKAGE INCLUDING THE SAME

(71) Applicant: SAMSUNG ELECTRONICS CO., LTD., Suwon-si (KR)

(72) Inventors: Juwon KIM, Suwon-si (KR); Seokbeom YONG, Suwon-si (KR)

(73) Assignee: SAMSUNG ELECTRONICS CO., LTD., Suwon-si (KR)

(21) Appl. No.: 19/084,163

(22) Filed: Mar. 19, 2025

(30) Foreign Application Priority Data
Oct. 2, 2024 (KR) 10-2024-0133905

(51) Int. Cl. H05K 1/11

(52) U.S. Cl. CPC H05K 1/115; H05K 2201/0338; H05K 2201/093; H05K 2201/09609; H05K 2201/09636

(57) ABSTRACT

A package substrate includes: a first wiring layer; and a second wiring layer, in which the first wiring layer includes: a plurality of first ground layers spaced apart from each other in a first direction perpendicular to a first surface of the first wiring layer; a plurality of first signal layers spaced apart from each other in the first direction, and spaced apart from the plurality of first ground layers along a second direction parallel to the first surface of the first wiring layer; a plurality of metal layers spaced apart from each other in the first direction between the plurality of first ground layers and the plurality of first signal layers, and spaced apart from the plurality of first ground layers and the plurality of first signal layers along the second direction; and a plurality of first insulating layers between the plurality of first ground layers.

### CROSS-REFERENCE TO RELATED APPLICATIONS

This U.S. non-provisional patent application claims priority under 35 U.S.C. § 119 of Korean Patent Application No. 10-2024-0133905, filed on Oct. 2, 2024, the entire contents of which are hereby incorporated by reference.

### BACKGROUND

The present disclosure herein relates to a package substrate and a semiconductor package including the same.

A semiconductor package is an implementation of an integrated circuit chip in a form suitable for use in an electronic product. In general, the semiconductor package is implemented by mounting a semiconductor chip on a printed circuit board (PCB), and electrically connecting them using a bonding wire or bump.

Recently, demand for a portable device is rapidly increasing in the electronics market, and thus a higher density of electronic components mounted on the electronics product is continuously required. Due to the higher density of electronic components, parasitic capacitance is increase, thereby degrading signal characteristics. Accordingly, various studies are being conducted on a multilayer printed circuit board (PCB) for mounting the electronic components at the higher density.

### SUMMARY

The present disclosure provides a package substrate with improved electrical characteristics and a semiconductor package including the same.

The present disclosure also provides a package substrate with excellent reliability and a semiconductor package including the same.

According to an aspect of the disclosure, a package substrate includes: a first wiring layer; and a second wiring layer on the first wiring layer, in which the first wiring layer includes: a plurality of first ground layers spaced apart from each other in a first direction perpendicular to a first surface of the first wiring layer; a plurality of first signal layers spaced apart from each other in the first direction, and spaced apart from the plurality of first ground layers along a second direction parallel to the first surface of the first wiring layer; a plurality of metal layers spaced apart from each other in the first direction between the plurality of first ground layers and the plurality of first signal layers, and spaced apart from the plurality of first ground layers and the plurality of first signal layers along the second direction; and a plurality of first insulating layers between the plurality of first ground layers, and extending between the plurality of metal layers, and between the plurality of first signal layers, and in which the first surface of the first wiring layer is a surface of an insulating layer among the plurality of first insulating layers.

According to an aspect of the disclosure, a package substrate including: a first wiring layer and a second wiring layer stacked along a first direction, in which the first wiring layer includes: a plurality of first ground layers spaced apart from each other in the first direction; a first insulating region penetrating the plurality of first ground layers and extending in the first direction; a plurality of first signal layers in the first insulating region, and spaced apart from each other in the first direction; and a plurality of metal layers in the first insulating region, and between the plurality of first ground layers and the plurality of first signal layers, and spaced apart from each other in the first direction, and in which the second wiring layer includes: a plurality of second ground layers spaced apart from each other in the first direction; a second insulating region penetrating the plurality of second ground layers, and extending in the first direction; and a plurality of second signal layers in the second insulating region, and spaced apart from each other in the first direction, in which the plurality of first ground layers and the plurality of metal layers are electrically connected to the second ground layers, and in which the plurality of first signal layers are electrically connected to the plurality of second signal layers.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view of a package substrate according to some embodiments of the present disclosure;

FIG. 2 is a cross-sectional view taken along A-A′ of FIG. 1;

FIG. 3 is a plan view of a package substrate according to some embodiments of the present disclosure;

FIGS. 4 to 8 are diagrams illustrating a method for manufacturing a package substrate according to some embodiments of the present disclosure, and are cross-sectional views corresponding to A-A′ of FIG. 1;

FIG. 9 is a plan view of a package substrate according to some embodiments of the present disclosure;

FIG. 10 is a cross-sectional view taken along A-A′ of FIG. 9;

FIG. 11 is a diagram illustrating a method for manufacturing a package substrate according to some embodiments of the present disclosure, and is a cross-sectional view corresponding to A-A′ of FIG. 9;

FIG. 12 is a plan view of a package substrate according to some embodiments of the present disclosure;

FIG. 13 is a cross-sectional view taken along A-A′ of FIG. 12;

FIG. 14 is a diagram illustrating a method for manufacturing a package substrate according to some embodiments of the present disclosure, and is a cross-sectional view corresponding to A-A′ of FIG. 12; and

FIG. 15 is a cross-sectional view of a semiconductor package according to some embodiments of the present disclosure.

### DETAILED DESCRIPTION

Hereinafter, the present disclosure will be described in detail by describing embodiments of the present disclosure with reference to the accompanying drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

A layer may be referred to as being a lower layer or an upper layer. As understood by one of ordinary skill in the art, a lower layer may be also referred to as a first layer and an upper layer may be referred to as a second layer. Furthermore, a lower layer may be referred to as a second layer and an upper layer may be referred to as a first layer.

A plurality of components may be described as being spaced apart from each other. In one or more examples, a plurality of components that are spaced apart from each other may be spaced apart from each other by an equal distance. In one or more examples, when a plurality of components are spaced apart, two or more components may be spaced apart by a distance that is different from the other components.

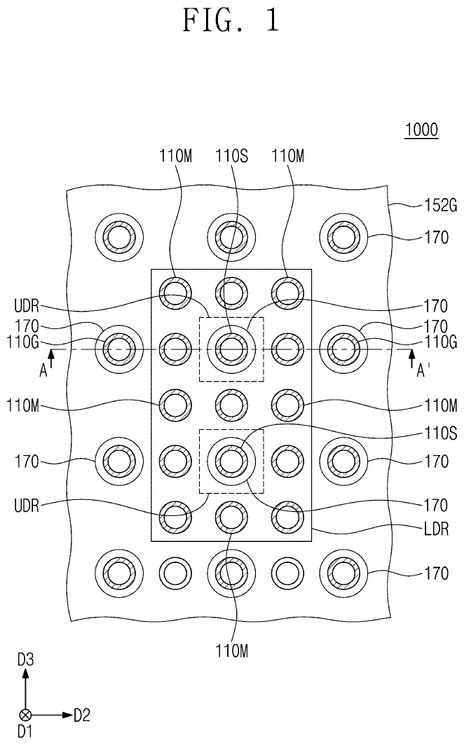

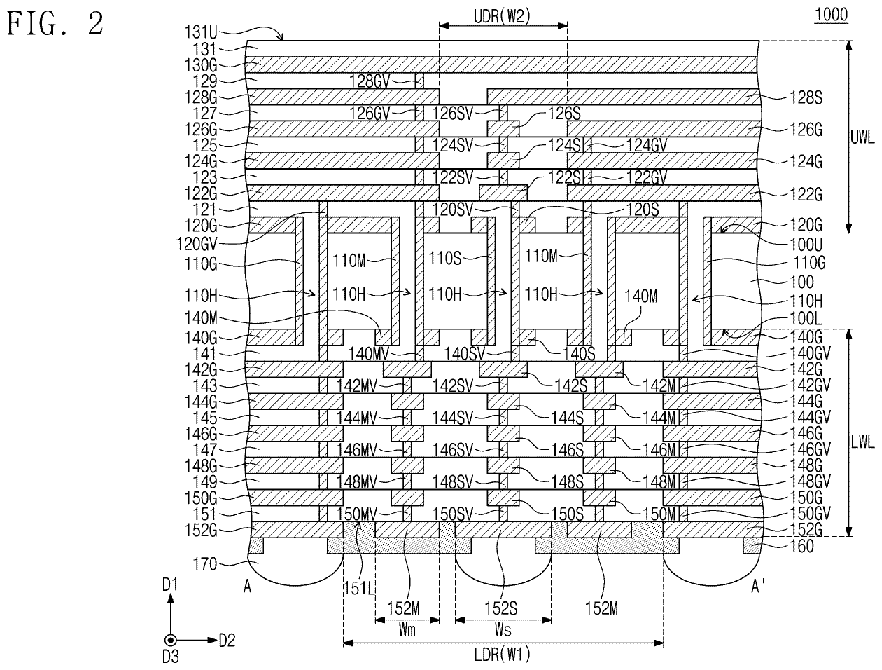

FIG. 1 is a plan view of a package substrate according to some embodiments of the present disclosure, and FIG. 2 is a cross-sectional view taken along A-A′ of FIG. 1.

Referring to FIGS. 1 and 2, a package substrate 1000 may include a lower wiring layer LWL and an upper wiring layer UWL on the lower wiring layer LWL. The lower wiring layer LWL and the upper wiring layer UWL may be stacked along a first direction D1. According to some embodiments, the package substrate 1000 may further include a core layer 100 between the lower wiring layer LWL and the upper wiring layer UWL. The core layer 100 may have an upper surface 100U and a lower surface 100L opposite of each other in the first direction D1, and the first direction D1 may be vertical to the upper surface 100U and the lower surface 100L of the core layer 100. The lower wiring layer LWL may be disposed on the lower surface 100L of the core layer 100, and the upper wiring layer UWL may be disposed on the upper surface 100U of the core layer 100. In one or more examples, a wiring layer in a semiconductor package may be a thin film of metal that creates conductive pathways between layers of a semiconductor chip. These pathways allow transistors to process information and communicate with each other.

The lower wiring layer LWL may include a plurality of lower ground layers 140G, 142G, 144G, 146G, 148G, 150G and 152G spaced apart from each other in the first direction D1. In one or more examples, the spacing between each of the lower ground layers may be spaced apart equally. In one or more examples, at least two of the lower ground layers may be spaced apart from each other at a distance that is different from the spacing of the other lower ground layers. The lower ground layers 140G, 142G, 144G, 146G, 148G, 150G and 152G may include a first lower ground layer 140G, a second lower ground layer 142G, a third lower ground layer 144G, a fourth lower ground layer 146G, a fifth lower ground layer 148G, a sixth lower ground layer 150G and a seventh lower ground layer 152G sequentially stacked on the lower surface 100L of the core layer 100. The seventh lower ground layer 152G may be referred to as a lowermost ground layer or lower ground pad. FIG. 2 illustrates that a number of the lower ground layers 140G, 142G, 144G, 146G, 148G, 150G and 152G is seven, but the present disclosure is not limited thereto. The lower ground layers 140G, 142G, 144G, 146G, 148G, 150G and 152G may extend parallel to each other along a second direction D2, and the second direction D2 may be parallel to the lower surface 100L of the core layer 100.

The lower wiring layer LWL may further include a plurality of lower signal layers 140S, 142S, 144S, 146S, 148S, 150S and 152S spaced apart from each other in the first direction D1. In one or more examples, the spacing between each of the lower signal layers may be spaced apart equally. In one or more examples, at least two of the lower signal layers may be spaced apart from each other at a distance that is different from the spacing of the other lower signal layers. The lower signal layers 140S, 142S, 144S, 146S, 148S, 150S and 152S may include a first lower signal layer 140S, a second lower signal layer 142S, a third lower signal layer 144S, a fourth lower signal layer 146S, a fifth lower signal layer 148S, a sixth lower signal layer 150S and a seventh lower signal layer 152S sequentially stacked on the lower surface 100L of the core layer 100. The seventh lower signal layer 152S may be referred to as a lowermost signal layer or lower signal pad. FIG. 2 illustrates that a number of the lower signal layers 140S, 142S, 144S, 146S, 148S, 150S and 152S is seven, but the present disclosure is not limited thereto. The lower signal layers 140S, 142S, 144S, 146S, 148S, 150S and 152S may extend parallel to each other along the second direction D2, and may be horizontally spaced apart from the lower ground layers 140G, 142G, 144G, 146G, 148G, 150G and 152G along the second direction D2. As understood by one of ordinary skill in the art, a signal layer in a semiconductor package may be a layer on a printed circuit board (PCB) that carries signals between components and integrated circuits (ICs). Signal layers may contain copper traces that transmit analog and digital signals.

The lower wiring layer LWL may further include a plurality of metal layers 140M, 142M, 144M, 146M, 148M, 150M and 152M spaced apart from each other in the first direction D1. In one or more examples, the spacing between each of the lower metal layers may be spaced apart equally. In one or more examples, at least two of the lower metal layers may be spaced apart from each other at a distance that is different from the spacing of the other lower metal layers. The metal layers 140M, 142M, 144M, 146M, 148M, 150M and 152M may include a first metal layer 140M, a second metal layer 142M, a third metal layer 144M, a fourth metal layer 146M, a fifth metal layer 148M, a sixth metal layer 150M and a seventh metal layer 152M sequentially stacked on the lower surface 100L of the core layer 100. The seventh metal layer 152M may be referred to as a lowermost metal layer. FIG. 2 illustrates that a number of the metal layers 140M, 142M, 144M, 146M, 148M, 150M and 152M is seven, but the present disclosure is not limited thereto. The metal layers 140M, 142M, 144M, 146M, 148M, 150M and 152M may extend parallel to each other along the second direction D2, and may be disposed between the lower ground layers 140G, 142G, 144G, 146G, 148G, 150G and 152G and the lower signal layers 140S, 142S, 144S, 146S, 148S, 150S and 152S. The metal layers 140M, 142M, 144M, 146M, 148M, 150M and 152M may be horizontally spaced apart from the lower ground layers 140G, 142G, 144G, 146G, 148G, 150G and 152G and the lower signal layers 140S, 142S, 144S, 146S, 148S, 150S and 152S along the second direction D2.

The lower wiring layer LWL may further include a plurality of lower insulating layers 141, 143, 145, 147, 149 and 151 interposed between the lower ground layers 140G, 142G, 144G, 146G, 148G, 150G and 152G, and extending between the metal layers 140M, 142M, 144M, 146M, 148M, 150M and 152M and between the lower signal layers 140S, 142S, 144S, 146S, 148S, 150S and 152S. The lower insulating layers 141, 143, 145, 147, 149 and 151 may include a first lower insulating layer 141, a second lower insulating layer 143, a third lower insulating layer 145, a fourth lower insulating layer 147, a fifth lower insulating layer 149 and a sixth lower insulating layer 151 sequentially stacked on the lower surface 100L of the core layer 100. The sixth lower insulating layer 151 may be referred to as a lowermost insulating layer. FIG. 2 illustrates that a number of the lower insulating layers 141, 143, 145, 147, 149 and 151 is six, but the present disclosure is not limited thereto. The lower insulating layers 141, 143, 145, 147, 149 and 151 may extend parallel to each other along the second direction D2. A lower surface 151L of the sixth lower insulating layer 151 (e.g., a lowermost insulating layer) may be referred to as a lower surface of the lower wiring layer LWL. The first direction D1 may be vertical to the lower surface 151L of the lower wiring layer LWL, and the second direction D2 may be parallel to the lower surface 151L of the lower wiring layer LWL.

The first lower ground layer 140G, the first metal layer 140M and the first lower signal layer 140S may be disposed on the lower surface 100L of the core layer 100, and may be spaced apart from each other in the second direction D2. The first lower insulating layer 141 may be disposed on the lower surface 100L of the core layer 100, and may cover the first lower ground layer 140G, the first metal layer 140M and the first lower signal layer 140S. The second lower ground layer 142G, the second metal layer 142M and the second lower signal layer 142S may be disposed on the first lower insulating layer 141, and may be spaced apart from each other in the second direction D2. The second lower insulating layer 143 may be disposed on the first lower insulating layer 141, and may cover the second lower ground layer 142G, the second metal layer 142M and the second lower signal layer 142S. The third lower ground layer 144G, the third metal layer 144M and the third lower signal layer 144S may be disposed on the second lower insulating layer 143, and may be spaced apart from each other in the second direction D2. The third lower insulating layer 145 may be disposed on the second lower insulating layer 143, and may cover the third lower ground layer 144G, the third metal layer 144M and the third lower signal layer 144S.

The fourth lower ground layer 146G, the fourth metal layer 146M and the fourth lower signal layer 146S may be disposed on the third lower insulating layer 145, and may be spaced apart from each other in the second direction D2. The fourth lower insulating layer 147 may be disposed on the third lower insulating layer 145, and may cover the fourth lower ground layer 146G, the fourth metal layer 146M and the fourth lower signal layer 146S. The fifth lower ground layer 148G, the fifth metal layer 148M and the fifth lower signal layer 148S may be disposed on the fourth lower insulating layer 147, and may be spaced apart from each other in the second direction D2. The fifth lower insulating layer 149 may be disposed on the fourth lower insulating layer 147, and may cover the fifth lower ground layer 148G, the fifth metal layer 148M and the fifth lower signal layer 148S. The sixth lower ground layer 150G, the sixth metal layer 150M and the sixth lower signal layer 150S may be disposed on the fifth lower insulating layer 149, and may be spaced apart from each other in the second direction D2. The sixth lower insulating layer 151 may be disposed on the fifth lower insulating layer 149, and may cover the sixth lower ground layer 150G, the sixth metal layer 150M and the sixth lower signal layer 150S.

The seventh lower ground layer 152G, the seventh metal layer 152M and the seventh lower signal layer 152S may be disposed on the sixth lower insulating layer 151, and may be spaced apart from each other in the second direction D2. The seventh lower ground layer 152G may function as a lower ground pad, and the seventh lower signal layer 152S may function as a lower signal pad.

The metal layers 140M, 142M, 144M, 146M, 148M, 150M and 152M may be aligned with each other in the first direction D1, and may be horizontally spaced apart from the lower ground layers 140G, 142G, 144G, 146G, 148G, 150G and 152G along the second direction D2. The metal layers 140M, 142M, 144M, 146M, 148M, 150M and 152M may not vertically overlap the lower ground layers 140G, 142G, 144G, 146G, 148G, 150G and 152G along the first direction D1.

The lower signal layers 140S, 142S, 144S, 146S, 148S, 150S and 152S may be aligned with each other in the first direction D1. The lower signal layers 140S, 142S, 144S, 146S, 148S, 150S and 152S may be horizontally spaced apart from the metal layers 140M, 142M, 144M, 146M, 148M, 150M and 152M along the second direction D2. The lower signal layers 140S, 142S, 144S, 146S, 148S, 150S and 152S may not vertically overlap the metal layers 140M, 142M, 144M, 146M, 148M, 150M and 152M along the first direction D1. The metal layers 140M, 142M, 144M, 146M, 148M, 150M and 152M may be disposed between the lower ground layers 140G, 142G, 144G, 146G, 148G, 150G and 152G and the lower signal layers 140S, 142S, 144S, 146S, 148S, 150S and 152S.

The lower wiring layer LWL may further include lower ground vias 140GV, 142GV, 144GV, 146GV, 148GV and 150GV respectively disposed between the lower ground layers 140G, 142G, 144G, 146G, 148G, 150G and 152G and in the lower insulating layers 141, 143, 145, 147, 149 and 151. The lower ground vias 140GV, 142GV, 144GV, 146GV, 148GV and 150GV may include a first lower ground via 140GV, a second lower ground via 142GV, a third lower ground via 144GV, a fourth lower ground via 146GV, a fifth lower ground via 148GV and a sixth lower ground via 150GV respectively disposed in the first to sixth lower insulating layers 141, 143, 145, 147, 149 and 151. FIG. 2 illustrates that a number of the lower ground vias 140GV, 142GV, 144GV, 146GV, 148GV and 150GV is six, but present disclosure is not limited thereto. The lower ground layers 140G, 142G, 144G, 146G, 148G, 150G and 152G may be electrically connected to each other through the lower ground vias 140GV, 142GV, 144GV, 146GV, 148GV and 150GV. In one or more examples, a ground via in a semiconductor package may be a hole drilled into a printed circuit board (PCB) to create an electrical connection between layers. The hole may be plated with a metal, such as copper, to create a connection through the insulating layers.

The lower wiring layer LWL may further include lower signal vias 140SV, 142SV, 144SV, 146SV, 148SV and 150SV respectively disposed between the lower signal layers 140S, 142S, 144S, 146S, 148S, 150S and 152S and in the lower insulating layers 141, 143, 145, 147, 149 and 151. The lower signal vias 140SV, 142SV, 144SV, 146SV, 148SV and 150SV may include a first lower signal via 140SV, a second lower signal via 142SV, a third lower signal via 144SV, a fourth lower signal via 146SV a fifth lower signal via 148SV and a sixth lower signal via 150SV respectively disposed in the first to sixth lower insulating layers 141, 143, 145, 147, 149 and 151. FIG. 2 illustrates that a number of the lower signal vias 140SV, 142SV, 144SV, 146SV, 148SV and 150SV is six, but the present disclosure is not limited thereto. The lower signal layers 140S, 142S, 144S, 146S, 148S, 150S and 152S may be electrically connected to each other through the lower signal vias 140SV, 142SV, 144SV, 146SV, 148SV and 150SV. In one or more examples, a semiconductor signal via is a hole that connects electrical signals between different layers of a semiconductor device.

The lower wiring layer LWL may further include metal vias 140MV, 142MV, 144MV, 146MV, 148MV, 150MV and 152MV respectively disposed between the metal layers 140M, 142M, 144M, 146M, 148M, 150M and 152M and in the lower insulating layers 141, 143, 145, 147, 149 and 151. The metal vias 140MV, 142MV, 144MV, 146MV, 148MV and 150MV may include a first metal via 140MV, a second metal via 142MV, a third metal via 144MV, a fourth metal via 146MV, a fifth metal via 148MV and a sixth metal via 150MV respectively disposed in the first to sixth lower insulating layers 141, 143, 145, 147, 149 and 151. FIG. 2 illustrates that a number of the metal vias 140MV, 142MV, 144MV, 146MV, 148MV and 150MV is six, but the present disclosure is not limited thereto. The metal layers 140M, 142M, 144M, 146M, 148M, 150M and 152M may be electrically connected to each other through the metal vias 140MV, 142MV, 144MV, 146MV, 148MV and 150MV.

The lower wiring layer LWL may include a lower insulating region LDR extending in the first direction D1 to penetrate the lower ground layers 140G, 142G, 144G, 146G, 148G, 150G and 152G. The lower insulating region LDR may include parts of the lower insulating layers 141, 143, 145, 147, 149 and 151. The lower signal layers 140S, 142S, 144S, 146S, 148S, 150S and 152S and the lower signal vias 140SV, 142SV, 144SV, 146SV, 148SV and 150SV may be disposed in the lower insulating region LDR, and may be separated from the lower ground layers 140G, 142G, 144G, 146G, 148G, 150G and 152G and the lower ground vias 140GV, 142GV, 144GV, 146GV, 148GV and 150GV by the lower insulating region LDR (e.g., the parts of the lower insulating layers 141, 143, 145, 147, 149 and 151). The metal layers 140M, 142M, 144M, 146M, 148M, 150M and 152M and the metal vias 140MV, 142MV, 144MV, 146MV, 148MV and 150MV may be disposed in the lower insulating region LDR, and may be separated from the lower ground layers 140G, 142G, 144G, 146G, 148G, 150G and 152G and the lower ground vias 140GV, 142GV, 144GV, 146GV, 148GV and 150GV by the lower insulating region LDR (e.g., the parts of the lower insulating layers 141, 143, 145, 147, 149 and 151). The lower signal layers 140S, 142S, 144S, 146S, 148S, 150S and 152S and the lower signal vias 140SV, 142SV, 144SV, 146SV, 148SV and 150SV may be separated from the metal layers 140M, 142M, 144M, 146M, 148M, 150M and 152M and the metal vias 140MV, 142MV, 144MV, 146MV, 148MV and 150MV by the lower insulating region LDR (e.g., the parts of the lower insulating layers 141, 143, 145, 147, 149 and 151).

A width W1 along the second direction D2 of the lower insulating region LDR may be greater than a maximum width Ws along the second direction D2 of the lower signal layers 140S, 142S, 144S, 146S, 148S, 150S and 152S, and may be greater than a sum of the maximum width Ws along the second direction D2 of the lower signal layers 140S, 142S, 144S, 146S, 148S, 150S and 152S and a maximum width Wm along the second direction D2 of the metal layers 140M, 142M, 144M, 146M, 148M, 150M and 152M (W1>Ws+Wm).

The lower ground layers 140G, 142G, 144G, 146G, 148G, 150G and 152G, the lower ground vias 140GV, 142GV, 144GV, 146GV, 148GV and 150GV, the lower signal layers 140S, 142S, 144S, 146S, 148S, 150S and 152S, the lower signal vias 140SV, 142SV, 144SV, 146SV, 148SV and 150SV, the metal layers 140M, 142M, 144M, 146M, 148M, 150M and 152M and the metal vias 140MV, 142MV, 144MV, 146MV, 148MV, 150MV and 152MV may include metal, and may include, for example, copper (Cu), aluminum (Al), silver (Ag), tin (Sn), gold (Au), nickel (Ni), lead (Pb), titanium (Ti), or a combination thereof. The lower insulating layers 141, 143, 145, 147, 149 and 151 may include an insulating material, and may include, for example, prepreg, an aginomoto buildup film (ABF), FR-4 or bismaleimide triazine (BT).

The package substrate 1000 may further include a lower solder mask layer 160 disposed on the lower surface 151L (e.g., a lower surface of the lowermost insulating layer 151) of the lower wiring layer LWL. The lower solder mask layer 160 may expose a lower surface of the lowermost ground layer 152G and a lower surface of the lowermost signal layer 152S, and may cover the lowermost metal layer 152M. The lower solder mask layer 160 may cover a lower surface of the lowermost metal layer 152M. The lowermost metal layer 152M may be disposed inside the lower solder mask layer 160, and may be sealed by the lower solder mask layer 160. For example, the lower solder mask layer 160 may be a solder mask or solder resist, and may include an insulating material. In one or more examples, the solder mask layer 160 may be a protective polymer coating applied on a surface of a wafer to prevent unwanted solder from bridging between to two elements (e.g., conductive pads), thereby acting as a barrier to protect specific areas from being soldered to.

The package substrate 1000 may further include connection terminals 170 respectively disposed on the exposed lower surfaces of the lowermost ground layer 152G and the lowermost signal layer 152S. The connection terminals 170 may include a solder ball, a solder bump or the like. The lowermost ground layer 152G may be referred to as a lower ground pad, and a ground voltage may be applied to the lower ground layers 140G, 142G, 144G, 146G, 148G, 150G and 152G and the lower ground vias 140GV, 142GV, 144GV, 146GV, 148GV and 150GV through a connection terminal 170 on the lower ground pad 152G. The lowermost signal layer 152S may be referred to as a lower signal pad, and a signal voltage may be applied to the lower signal layers 140S, 142S, 144S, 146S, 148S, 150S and 152S and the lower signal vias 140SV, 142SV, 144SV, 146SV, 148SV and 150SV through a connection terminal 170 on the lower signal pad 152S.

The package substrate 1000 may further include penetration vias 110G, 110M and 110S penetrating the core layer 100. Each of the penetration vias 110G, 110M and 110S may extend in the first direction D1 to penetrate the core layer 100. The penetration vias 110G, 110M and 110S may be spaced apart from each other in the second direction D2 in the core layer 100. According to some embodiments, each of the penetration vias 110G, 110M and 110S may have a shape of a hollow cylinder having an empty region 110H thereinside. For example, the penetration vias 110G, 110M and 110S may include a metal material such as copper (Cu) or tungsten (W). In one or more examples, a penetration via in a semiconductor package may be a hole in a semiconductor substrate to connect signal lines. The penetration via may pass through multiple layers in a semiconductor package to create an electrical connection. In one or more examples, the metal material such as Cu or W may facilitate a connection between layers in the semiconductor package.

According to some embodiments, the core layer 100 may include an insulating material, and may include, for example, at least one of glass, ceramic or an epoxy resin. According to other embodiments, the core layer 100 may include metal, and may include, for example, stainless steel, aluminum (Al), nickel (Ni), magnesium (Mg), zinc (Zn), tantalum (Ta) or a combination thereof. When the core layer 100 includes metal, an insulating layer may be additionally disposed between each of the penetration vias 110G, 110M and 110S and the core layer 100, and each of the penetration vias 110G, 110M and 110S may be separated from the core layer 100 by the insulating layer.

The first lower ground layer 140G may be connected to a ground penetration via 110G among the penetration vias 110G, 110M and 110S. The ground penetration via 110G may be electrically connected to the lower ground layers 140G, 142G, 144G, 146G, 148G, 150G and 152G and the lower ground vias 140GV, 142GV, 144GV, 146GV, 148GV and 150GV. The first metal layer 140M may be connected to a metal penetration via 110M among the penetration vias 110G, 110M and 110S. The metal penetration via 110M may be electrically connected to the metal layers 140M, 142M, 144M, 146M, 148M, 150M and 152M and the metal vias 140MV, 142MV, 144MV, 146MV, 148MV, 150MV and 152MV. The first lower signal layer 140S may be connected to a signal penetration via 110S among the penetration vias 110G, 110M and 110S. The signal penetration via 110S may be electrically connected to the lower signal layers 140S, 142S, 144S, 146S, 148S, 150S and 152S and the lower signal vias 140SV, 142SV, 144SV, 146SV, 148SV and 150SV. The ground penetration via 110G, the metal penetration via 110M and the signal penetration via 110S may be spaced apart from each other along the second direction D2, and the metal penetration via 110M may be disposed between the ground penetration via 110G and the signal penetration via 110S.

The upper wiring layer UWL may include a plurality of upper ground layers 120G, 122G, 124G, 126G, 128G and 130G spaced apart from each other in the first direction D1. In one or more examples, the spacing between each of the upper ground layers may be spaced apart equally. In one or more examples, at least two of the upper ground layers may be spaced apart from each other at a distance that is different from the spacing of the other upper ground layers. The upper ground layers 120G, 122G, 124G, 126G, 128G and 130G may include a first upper ground layer 120G, a second upper ground layer 122G, a third upper ground layer 124G, a fourth upper ground layer 126G, a fifth upper ground layer 128G and a sixth upper ground layer 130G sequentially stacked on the upper surface 100U of the core layer 100. FIG. 2 illustrates that a number of the upper ground layers 120G, 122G, 124G, 126G, 128G and 130G is six, but the present disclosure is not limited thereto. The upper ground layers 120G, 122G, 124G, 126G, 128G and 130G may extend parallel to each other along the second direction D2, and the second direction D2 may be parallel to the upper surface 100U of the core layer 100.

The upper wiring layer UWL may further include a plurality of upper signal layers 120S, 122S, 124S, 126S and 128S spaced apart from each other in the first direction D1. In one or more examples, the spacing between each of the upper signal layers may be spaced apart equally. In one or more examples, at least two of the upper signal layers may be spaced apart from each other at a distance that is different from the spacing of the other upper signal layers. The upper signal layers 120S, 122S, 124S, 126S and 128S may include a first upper signal layer 120S, a second upper signal layer 122S, a third upper signal layer 124S, a fourth upper signal layer 126S and a fifth upper signal layer 128S sequentially stacked on the upper surface 100U of the core layer 100. FIG. 2 illustrates that a number of the upper signal layers 120S, 122S, 124S, 126S and 128S is five, but the present disclosure is not limited thereto. The upper signal layers 120S, 122S, 124S, 126S and 128S may extend parallel to each other along the second direction D2, and may be horizontally spaced apart from the upper ground layers 120G, 122G, 124G, 126G, 128G and 130G along the second direction D2.

The upper wiring layer UWL may further include a plurality of upper insulating layers 121, 123, 125, 127, 129 and 131 respectively disposed on the upper ground layers 120G, 122G, 124G, 126G, 128G and 130G and respectively extending onto the upper signal layers 120S, 122S, 124S, 126S and 128S. The upper insulating layers 121, 123, 125, 127, 129 and 131 may include a first upper insulating layer 121, a second upper insulating layer 123, a third upper insulating layer 125, a fourth upper insulating layer 127, a fifth upper insulating layer 129 and a sixth upper insulating layer 131 sequentially stacked on the upper surface 100U of the core layer 100. The sixth upper insulating layer 131 may be referred to as an uppermost insulating layer. FIG. 2 illustrates that a number of the upper insulating layers 121, 123, 125, 127, 129 and 131 is six, but the present disclosure is not limited thereto. The upper insulating layers 121, 123, 125, 127, 129 and 131 may extend parallel to each other along the second direction D2. An upper surface 131U of the sixth upper insulating layer 131 (e.g., an uppermost insulating layer) may be referred to as an upper surface of the upper wiring layer UWL. The first direction D1 may be vertical to the upper surface 131U of the upper wiring layer UWL, and the second direction D2 may be parallel to the upper surface 131U of the upper wiring layer UWL.

The first upper ground layer 120G and the first upper signal layer 120S may be disposed on the upper surface 100U of the core layer 100, and may be spaced apart from each other in the second direction D2. The first upper insulating layer 121 may be disposed on the upper surface 100U of the core layer 100, and may cover the first upper ground layer 120G and the first upper signal layer 120S. The second upper ground layer 122G and the second upper signal layer 122S may be disposed on the first upper insulating layer 121, and may be spaced apart from each other in the second direction D2. The second upper insulating layer 123 may be disposed on the first upper insulating layer 121, and may cover the second upper ground layer 122G and the second upper signal layer 122S. The third upper ground layer 124G and the third upper signal layer 124S may be disposed on the second upper insulating layer 123, and may be spaced apart from each other in the second direction D2. The third upper insulating layer 125 may be disposed on the second upper insulating layer 123, and may cover the third upper ground layer 124G and the third upper signal layer 124S.

The fourth upper ground layer 126G and the fourth upper signal layer 126S may be disposed on the third upper insulating layer 125, and may be spaced apart from each other in the second direction D2. The fourth upper insulating layer 127 may be disposed on the third upper insulating layer 125, and may cover the fourth upper ground layer 126G and the fourth upper signal layer 126S. The fifth upper ground layer 128G and the fifth upper signal layer 128S may be disposed on the fourth upper insulating layer 127, and may be spaced apart from each other in the second direction D2. The fifth upper insulating layer 129 may be disposed on the fourth upper insulating layer 127, and may cover the fifth upper ground layer 128G and the fifth upper signal layer 128S. The sixth upper ground layer 130G may be disposed on the fifth upper insulating layer 129, and may extend in the second direction D2. The sixth upper insulating layer 131 may be disposed on the fifth upper insulating layer 129, and may cover the sixth upper ground layer 130G.

Although not shown, an upper ground pad and an upper signal pad may be disposed on the upper surface 131U (e.g., an upper surface of the sixth upper insulating layer 131) of the upper wiring layer UWL. The upper ground layers 120G, 122G, 124G, 126G, 128G and 130G may be electrically connected to the upper ground pad, and the upper signal layers 120S, 122S, 124S, 126S and 128S may be electrically connected to the upper signal pad.

The upper wiring layer UWL may further include upper ground vias 120GV, 122GV, 124GV, 126GV and 128GV respectively disposed between the upper ground layers 120G, 122G, 124G, 126G, 128G and 130G and in the upper insulating layers 121, 123, 125, 127, 129 and 131. The upper ground vias 120GV, 122GV, 124GV, 126GV and 128GV may include a first upper ground via 120GV, a second upper ground via 122GV, a third upper ground via 124GV, a fourth upper ground via 126GV, a fifth upper ground via 128GV and a sixth upper ground via (not shown) respectively disposed in the first to sixth upper insulating layers 121, 123, 125, 127, 129 and 131. It is described that a number of the upper ground vias 120GV, 122GV, 124GV, 126GV and 128GV is six, but the present disclosure is not limited thereto. The upper ground layers 120G, 122G, 124G, 126G, 128G and 130G may be electrically connected to each other through the upper ground vias 120GV, 122GV, 124GV, 126GV and 128GV, and may be electrically connected to the upper ground pad.

The upper wiring layer UWL may further include upper signal vias 120SV, 122SV, 124SV, and 126SV respectively disposed between the upper signal layers 120S, 122S, 124S, 126S and 128S and in the upper insulating layers 121, 123, 125, 127, 129 and 131. The upper signal vias 120SV, 122SV, 124SV, and 126SV may include a first upper signal via 120SV, a second upper signal via 122SV, a third upper signal via 124SV, a fourth upper signal via 126SV, a fifth upper signal via (not shown) and a sixth upper signal via (not shown) respectively disposed in the first to sixth upper insulating layers 121, 123, 125, 127, 129 and 131. It is described that a number of the upper signal vias 120SV, 122SV, 124SV, and 126SV is six, but the present disclosure is not limited thereto. The upper signal layers 120S, 122S, 124S, 126S and 128S may be electrically connected to each other through the upper signal vias 120SV, 122SV, 124SV, and 126SV, and may be electrically connected to the upper signal pad.

The upper wiring layer UWL may include an upper insulating region UDR extending in the first direction D1 to at least partially penetrate the upper ground layers 120G, 122G, 124G, 126G, 128G and 130G. The upper insulating region UDR may include parts of the upper insulating layers 121, 123, 125, 127, 129 and 131. The upper signal layers 120S, 122S, 124S, 126S and 128S and the upper signal vias 120SV, 122SV, 124SV, and 126SV may be disposed in the upper insulating region UDR, and may be separated from the upper ground layers 120G, 122G, 124G, 126G, 128G and 130G and the upper ground vias 120GV, 122GV, 124GV, 126GV and 128GV by the upper insulating region UDR (e.g., the parts of the upper insulating layers 121, 123, 125, 127, 129 and 131). The upper signal layers 120S, 122S, 124S, 126S and 128S and the upper signal vias 120SV, 122SV, 124SV, and 126SV may be spaced apart from the upper ground layers 120G, 122G, 124G, 126G, 128G and 130G and the upper ground vias 120GV, 122GV, 124GV, 126GV and 128GV along the second direction D2. A width W2 along the second direction D2 of the upper insulating region UDR may be smaller than the width W1 along the second direction D2 of the lower insulating region LDR.

The upper ground layers 120G, 122G, 124G, 126G, 128G and 130G, the upper ground vias 120GV, 122GV, 124GV, 126GV and 128GV, the upper signal layers 120S, 122S, 124S, 126S and 128S and the upper signal vias 120SV, 122SV, 124SV, and 126SV may include metal, and may include, for example, copper (Cu), aluminum (Al), silver (Ag), tin (Sn), gold (Au), nickel (Ni), lead (Pb), titanium (Ti) or a combination thereof. The upper insulating layers 121, 123, 125, 127, 129 and 131 may include an insulating material, and may include, for example, prepreg, an aginomoto buildup film (ABF), FR-4 or bismaleimide triazine (BT).

The first upper ground layer 120G may be connected to the ground penetration via 110G and the metal penetration via 110M among the penetration vias 110G, 110M and 110S. The ground penetration via 110G and the metal penetration via 110M may be electrically connected to the upper ground layers 120G, 122G, 124G, 126G, 128G and 130G and the upper ground vias 120GV, 122GV, 124GV, 126GV and 128GV. The lower ground layers 140G, 142G, 144G, 146G, 148G, 150G and 152G and the lower ground vias 140GV, 142GV, 144GV, 146GV, 148GV and 150GV may be electrically connected to the upper ground layers 120G, 122G, 124G, 126G, 128G and 130G and the upper ground vias 120GV, 122GV, 124GV, 126GV and 128GV through the ground penetration via 110G. The metal layers 140M, 142M, 144M, 146M, 148M, 150M and 152M and the metal vias 140MV, 142MV, 144MV, 146MV, 148MV, 150MV and 152MV may be electrically connected to the upper ground layers 120G, 122G, 124G, 126G, 128G and 130G and the upper ground vias 120GV, 122GV, 124GV, 126GV and 128GV through the metal penetration via 110M.

The first upper signal layer 120S may be connected to the signal penetration via 110S among the penetration vias 110G, 110M and 110S. The signal penetration via 110S may be electrically connected to the upper signal layers 120S, 122S, 124S, 126S and 128S and the upper signal vias 120SV, 122SV, 124SV, and 126SV. The lower signal layers 140S, 142S, 144S, 146S, 148S, 150S and 152S and the lower signal vias 140SV, 142SV, 144SV, 146SV, 148SV and 150SV may be electrically connected to the upper signal layers 120S, 122S, 124S, 126S and 128S and the upper signal vias 120SV, 122SV, 124SV, and 126SV through the signal penetration via 110S.

The penetration vias 110G, 110M and 110S may include a plurality of signal penetration vias 110S, and for example, the signal penetration vias 110S may be horizontally spaced apart from each other along a third direction D3. The third direction D3 may be parallel to the lower surface 100L and the upper surface 100U of the core layer 100, and may cross the second direction D2. The lower signal layers 140S, 142S, 144S, 146S, 148S, 150S and 152S and the lower signal vias 140SV, 142SV, 144SV, 146SV, 148SV and 150SV may be referred to as a lower signal group. A plurality of lower signal groups may be respectively disposed on the signal penetration vias 110S, and may be respectively connected to the signal penetration vias 110S.

The penetration vias 110G, 110M and 110S may include a plurality of metal penetration vias 110M, and for example, the metal penetration vias 110M may be horizontally spaced apart from each other along the second direction D2 and the third direction D3. The metal penetration vias 110M may be disposed so as to surround the signal penetration vias 110S. The metal layers 140M, 142M, 144M, 146M, 148M, 150M and 152M and the metal vias 140MV, 142MV, 144MV, 146MV, 148MV, 150MV and 152MV may be referred to as a metal pattern group. A plurality of metal pattern groups may be respectively disposed on the metal penetration vias 110M, and may be respectively connected to the metal penetration vias 110M.

The penetration vias 110G, 110M and 110S may include a plurality of ground penetration vias 110G, and for example, the ground penetration vias 110G may be horizontally spaced apart from each other along the second direction D2 and the third direction D3. The ground penetration vias 110G may be disposed so as to surround the metal penetration vias 110M and the signal penetration vias 110S. The metal penetration vias 110M may be disposed between the signal penetration vias 110S and the ground penetration vias 110G. The lower ground layers 140G, 142G, 144G, 146G, 148G, 150G and 152G and the lower ground vias 140GV, 142GV, 144GV, 146GV, 148GV and 150GV may be referred to as a lower ground group. The lower ground group may be disposed on the ground penetration vias 110G, and may be connected to the ground penetration vias 110G.

The lower insulating region LDR may penetrate the lower ground layers 140G, 142G, 144G, 146G, 148G, 150G and 152G along the first direction D1, and may extend in the second direction D2 and the third direction D3. The plurality of lower signal groups respectively disposed on the signal penetration vias 110S, and the plurality of metal pattern groups respectively disposed on the metal penetration vias 110M may be disposed in the lower insulating region LDR. The plurality of lower signal groups and the plurality of metal pattern groups may be horizontally (e.g., along the second direction D2 and the third direction D3) spaced apart from the lower ground group by the lower insulating region LDR.

The upper signal layers 120S, 122S, 124S, 126S and 128S and the upper signal vias 120SV, 122SV, 124SV, and 126SV may be referred to as an upper signal group. A plurality of upper signal groups may be respectively disposed on the signal penetration vias 110S, and may be respectively connected to the signal penetration vias 110S. The upper ground layers 120G, 122G, 124G, 126G, 128G and 130G and the upper ground vias 120GV, 122GV, 124GV, 126GV and 128GV may be referred to as an upper ground group. The upper ground group may be disposed on the ground penetration vias 110G and the metal penetration vias 110M, and may be connected to the ground penetration vias 110G and the metal penetration vias 110M.

The upper insulating region UDR may extend in the first direction D1 to at least partially penetrate the upper ground layers 120G, 122G, 124G, 126G, 128G and 130G. The upper insulating region UDR may be disposed so as to vertically (e.g., in the first direction D1) overlap the lower insulating region LDR. A plurality of upper insulating regions UDR may be horizontally (e.g., in the third direction D3) spaced apart from each other, and may vertically (e.g., in the first direction D1) overlap the lower insulating region LDR. The plurality of upper signal groups respectively disposed on the signal penetration vias 110S may be respectively disposed in the plurality of upper insulating regions UDR. Each of the plurality of upper signal groups may be horizontally (e.g., along the second direction D2 and the third direction D3) spaced apart from the upper ground group by each of the plurality of upper insulating regions UDR.

When the lower signal layers 140S, 142S, 144S, 146S, 148S, 150S and 152S and the lower signal vias 140SV, 142SV, 144SV, 146SV, 148SV and 150SV are disposed adjacent to the lower ground layers 140G, 142G, 144G, 146G, 148G, 150G and 152G and the lower ground vias 140GV, 142GV, 144GV, 146GV, 148GV and 150GV, parasitic capacitance therebetween may increase, and thus, signal characteristics applied to the lower signal layers 140S, 142S, 144S, 146S, 148S, 150S and 152S and the lower signal vias 140SV, 142SV, 144SV, 146SV, 148SV and 150SV may be deteriorated. In addition, when the lower signal layers 140S, 142S, 144S, 146S, 148S, 150S and 152S and the lower signal vias 140SV, 142SV, 144SV, 146SV, 148SV and 150SV are disposed relatively far from the lower ground layers 140G, 142G, 144G, 146G, 148G, 150G and 152G and the lower ground vias 140GV, 142GV, 144GV, 146GV, 148GV and 150GV, the lower insulating layers 141, 143, 145, 147, 149 and 151 that fill spaces therebetween may break, and thus, reliability of the package substrate 1000 may be deteriorated.

According to the present disclosure, the lower signal group including the lower signal layers 140S, 142S, 144S, 146S, 148S, 150S and 152S and the lower signal vias 140SV, 142SV, 144SV, 146SV, 148SV and 150SV may be disposed in the lower insulating region LDR. The metal pattern group including the metal layers 140M, 142M, 144M, 146M, 148M, 150M and 152M and the metal vias 140MV, 142MV, 144MV, 146MV, 148MV, 150MV and 152MV may be disposed in the lower insulating region LDR, and may be disposed between the lower ground group including the lower ground layers 140G, 142G, 144G, 146G, 148G, 150G and 152G and the lower ground vias 140GV, 142GV, 144GV, 146GV, 148GV and 150GV and the lower signal group. The metal pattern group may be horizontally (e.g., in the second direction D2 or the third direction D3) spaced apart from the lower signal group by a required distance, in the lower insulating region LDR, and may be disposed between the lower signal group and the lower ground group. Accordingly, the lower signal group may be horizontally (e.g., in the second direction D2 or the third direction D3) spaced apart from the lower ground group and the metal pattern group by a required distance, and thus, the parasitic capacitance therebetween may be reduced. As a result, impedance characteristics of a signal applied to the lower signal layers 140S, 142S, 144S, 146S, 148S, 150S and 152S and the lower signal vias 140SV, 142SV, 144SV, 146SV, 148SV and 150SV may be improved.

In addition, since the metal pattern group is disposed in the lower insulating region LDR between the lower signal group and the lower ground group, breaking the lower insulating layers 141, 143, 145, 147, 149 and 151 in the lower insulating region LDR may be suppressed. As a result, reliability of the package substrate 1000 may be improved.

Accordingly, electrical characteristics and reliability of the package substrate 1000 may be improved.

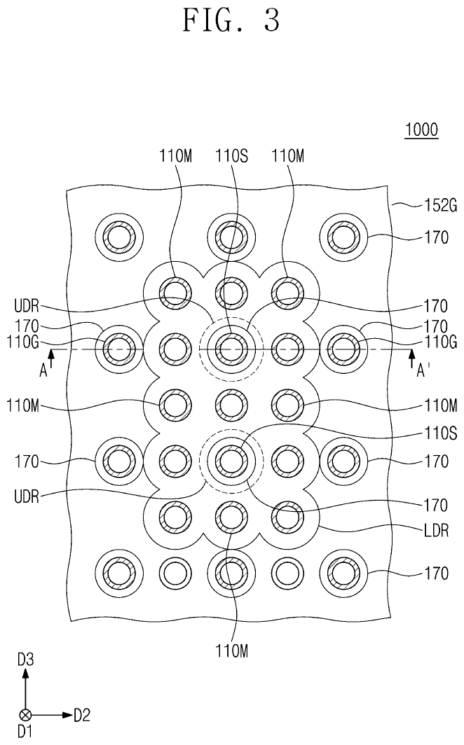

FIG. 3 is a plan view of a package substrate according to some embodiments of the present disclosure. A cross-sectional view taken along A-A′ of FIG. 3 is substantially the same as FIG. 2. In order to simplify description, a difference from the package substrate described with reference to FIGS. 1 and 2 will be mainly described.

Referring to FIGS. 2 and 3, the lower insulating region LDR may penetrate the lower ground layers 140G, 142G, 144G, 146G, 148G, 150G and 152G along the first direction D1, and may extend in the second direction D2 and the third direction D3. According to some embodiments, the lower insulating region LDR may have side surfaces extending in the second direction D2 and the third direction D3, and each of the side surfaces of the lower insulating region LDR may have a plurality of protruding surfaces convex toward the lower ground layers 140G, 142G, 144G, 146G, 148G, 150G and 152G. Each of the side surfaces of the lower insulating region LDR may have a shape in which the plurality of protruding surfaces are arranged in the second direction D2 or the third direction D3.

The upper insulating region UDR may extend in the first direction D1 to at least partially penetrate the upper ground layers 120G, 122G, 124G, 126G, 128G and 130G. The upper insulating region UDR may be disposed so as to vertically (e.g., in the first direction D1) overlap the lower insulating region LDR. A plurality of upper insulating regions UDR may be horizontally (e.g., in the third direction D3) spaced apart from each other, and may vertically (e.g., in the first direction D1) overlap the lower insulating region LDR. According to some embodiments, a planar shape of each of the plurality of upper insulating regions UDR may be a circular shape.

Except for what is described above, the package substrate according to the present embodiments is substantially the same as the package substrate described with reference to FIGS. 1 and 2.

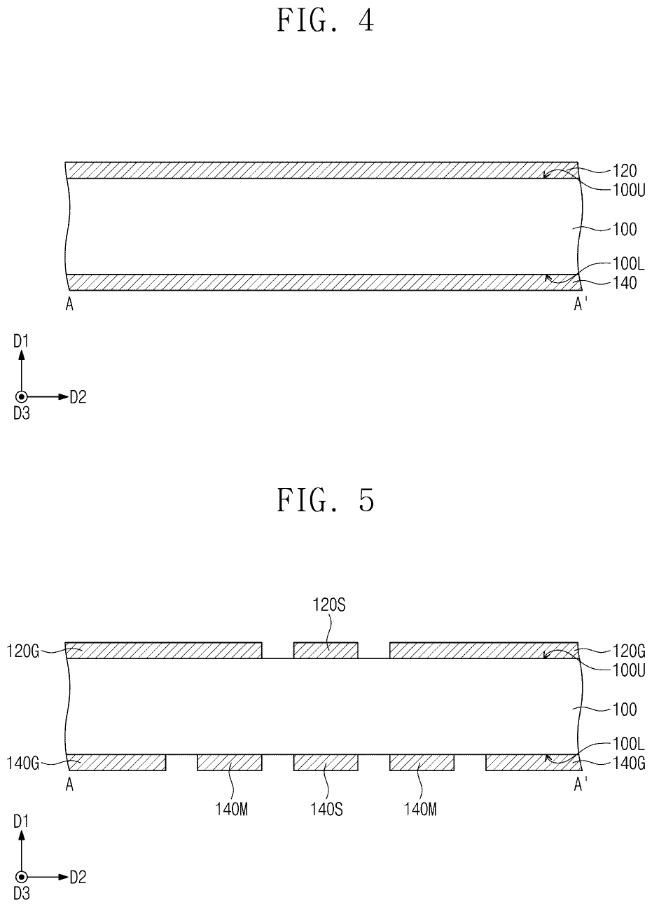

FIGS. 4 to 8 are diagrams illustrating a method for manufacturing a package substrate according to some embodiments of the present disclosure, and are cross-sectional views corresponding to A-A′ of FIG. 1. In order to simplify description, duplicate description of the package substrate described with reference to FIGS. 1 to 3 will be omitted.

Referring to FIG. 4, a core layer 100 may be provided. The core layer 100 may have an upper surface 100U and a lower surface 100L opposed to each other in the first direction D1. A first lower conductive layer 140 may be formed on the lower surface 100L of the core layer 100, and a first upper conductive layer 120 may be formed on the upper surface 100U of the core layer 100. For example, the first lower conductive layer 140 and the first upper conductive layer 120 may be formed using chemical vapor deposition, physical vapor deposition, or an electroplating method. In or more examples, the core layer 100 may be made of glass, polymer, or any other suitable material known to one of ordinary skill in the art.

Referring to FIG. 5, a first lower ground layer 140G, a first metal layer 140M and a first lower signal layer 140S may be formed by patterning the first lower conductive layer 140. A first upper ground layer 120G and a first upper signal layer 120S may be formed by patterning the first upper conductive layer 120.

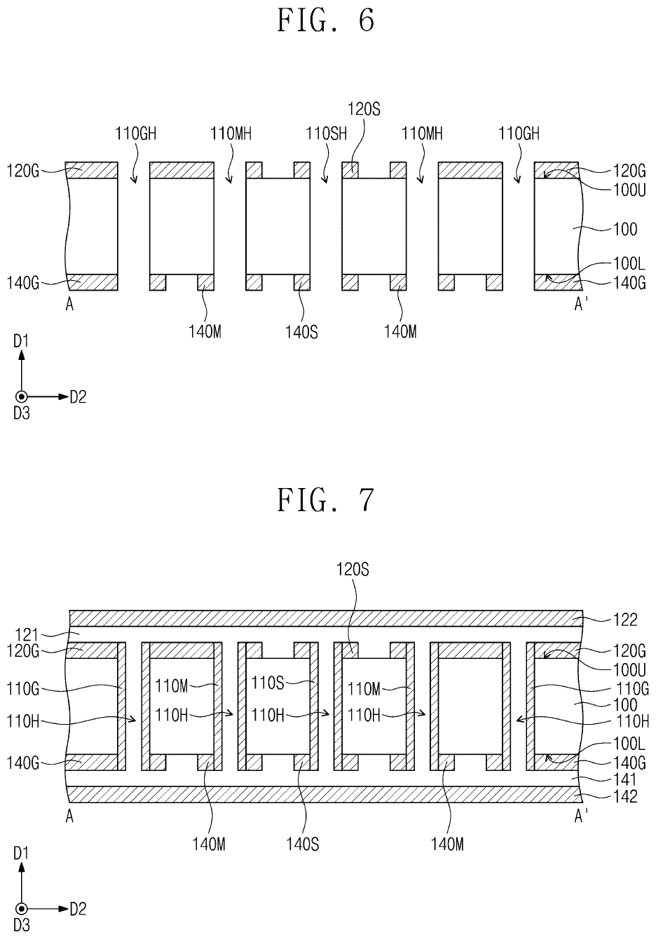

Referring to FIG. 6, penetration via holes 110GH, 110MH and 110SH penetrating the core layer 100 may be formed. Each of the penetration via holes 110GH, 110MH and 110SH may extend in the first direction D1 to penetrate the core layer 100. The penetration via holes 110GH, 110MH and 110SH may be spaced apart from each other in the core layer 100 in the second direction D2.

The penetration via holes 110GH, 110MH and 110SH may include a ground penetration via hole 110GH penetrating the first lower ground layer 140G and the first upper ground layer 120G. The ground penetration via hole 110GH may extend in the first direction D1 to penetrate the core layer 100, the first lower ground layer 140G and the first upper ground layer 120G. The penetration via holes 110GH, 110MH and 110SH may include a metal penetration via hole 110MH penetrating the first metal layer 140M and the first upper ground layer 120G. The metal penetration via hole 110MH may extend in the first direction D1 to penetrate the core layer 100, the first metal layer 140M and the first upper ground layer 120G. The penetration via holes 110GH, 110MH and 110SH may include a signal penetration via hole 110SH penetrating the first lower signal layer 140S and the first upper signal layer 120S. The signal penetration via hole 110SH may extend in the first direction D1 to penetrate the core layer 100, the first lower signal layer 140S and the first upper signal layer 120S.

Referring to FIG. 7, penetration vias 110G, 110M and 110S may be respectively formed in the penetration via holes 110GH, 110MH and 110SH. For example, forming the penetration vias 110G, 110M and 110S may include forming a penetration via conductive layer conformally covering inner surfaces of the penetration via holes 110GH, 110MH and 110SH. Accordingly, each of the penetration vias 110G, 110M and 110S may be formed so as to have a hollow cylinder shape having an empty region 110H thereinside. However, as understood by one of ordinary skill in the art, the embodiments are not limited these configurations, and the penetration vias may be any suitable shape known to one of ordinary skill in the art. In one or more examples, each of the penetration vias may have the same size and/or shape. In one or more examples, the size or shape of two penetration vias may be different from each other.

The penetration vias 110G, 110M and 110S may include a ground penetration via 110G formed in the ground penetration via hole 110GH, and connected to the first lower ground layer 140G and the first upper ground layer 120G, a metal penetration via 110M formed in the metal penetration via hole 110MH, and connected to the first metal layer 140M and the first upper ground layer 120G, and a signal penetration via 110S formed in the signal penetration via hole 110SH, and connected to the first lower signal layer 140S and the first upper signal layer 120S.

A first lower insulating layer 141 may be formed on a lower surface 100L of the core layer 100, and may cover the first lower ground layer 140G, the first metal layer 140M and the first lower signal layer 140S. A first upper insulating layer 121 may be formed on an upper surface 100U of the core layer 100, and may cover the first upper ground layer 120G and the first upper signal layer 120S. Thereafter, a second lower conductive layer 142 may be formed on the first lower insulating layer 141, and a second upper conductive layer 122 may be formed on the first upper insulating layer 121. For example, the second lower conductive layer 142 and the second upper conductive layer 122 may be formed using chemical vapor deposition, physical vapor deposition, or an electroplating method.

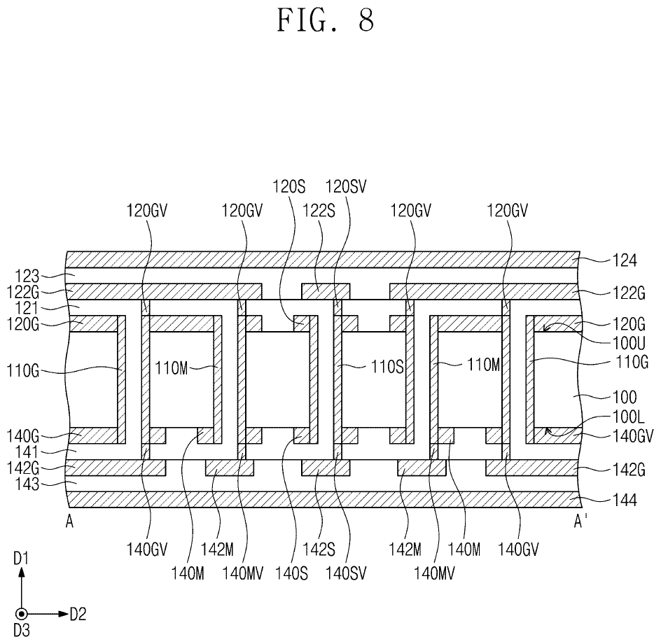

Referring to FIG. 8, a second lower ground layer 142G, a second metal layer 142M and a second lower signal layer 142S may be formed by patterning the second lower conductive layer 142. A first lower ground via 140GV, a first metal via 140MV and a first lower signal via 140SV may be formed in the first lower insulating layer 141. The first lower ground via 140GV may connect the first lower ground layer 140G and the second lower ground layer 142G, and the first metal via 140MV may connect the first metal layer 140M and the second metal layer 142M. The first lower signal via 140SV may connect the first lower signal layer 140S and the second lower signal layer 142S. For example, forming the first lower ground via 140GV, the first metal via 140MV and the first lower signal via 140SV may include forming a first lower ground via hole penetrating the first lower insulating layer 141, the first lower ground layer 140G and the second lower ground layer 142G, a first metal via hole penetrating the first lower insulating layer 141, the first metal layer 140M and the second metal layer 142M, and a first lower signal via hole penetrating the first lower insulating layer 141, the first lower signal layer 140S and the second lower signal layer 142S, and forming a conductive layer that fills the first lower ground via hole, the first metal via hole and the first lower signal via hole.

A second upper ground layer 122G and a second upper signal layer 122S may be formed by patterning the second upper conductive layer 122. A first upper ground via 120GV and a first upper signal via 120SV may be formed in the first upper insulating layer 121. The first upper ground via 120GV may connect the first upper ground layer 120G and the second upper ground layer 122G, and the first upper signal via 120SV may connect the first upper signal layer 120S and the second upper signal layer 122S. For example, forming the first upper ground via 120GV and the first upper signal via 120SV may include forming a first upper ground via hole penetrating the first upper insulating layer 121, the first upper ground layer 120G and the second upper ground layer 122G, and a first upper signal via hole penetrating the first upper insulating layer 121, the first upper signal layer 120S and the second upper signal layer 122S, and forming a conductive layer that fills the first upper ground via hole and the first upper signal via hole.

A second lower insulating layer 143 may be formed on the first lower insulating layer 141, and may cover the second lower ground layer 142G, the second metal layer 142M and the second lower signal layer 142S. A second upper insulating layer 123 may be formed on the first upper insulating layer 121, and may cover the second upper ground layer 122G and the second upper signal layer 122S. Thereafter, a third lower conductive layer 144 may be formed on the second lower insulating layer 143, and a third upper conductive layer 124 may be formed on the second upper insulating layer 123. For example, the third lower conductive layer 144 and the third upper conductive layer 124 may be formed using chemical vapor deposition, physical vapor deposition, or an electroplating method.

Referring back to FIG. 2, a third lower ground layer 144G, a third metal layer 144M and a third lower signal layer 144S may be formed by patterning the third lower conductive layer 144. A third upper ground layer 124G and a third upper signal layer 124S may be formed by patterning the third upper conductive layer 124. Thereafter, fourth to seventh lower ground layers 146G, 148G, 150G and 152G, fourth to seventh metal layers 146M, 148M, 150M and 152M, fourth to seventh lower signal layers 146S, 148S, 150S and 152S, third to sixth lower insulating layers 145, 147, 149 and 151, second to sixth lower ground vias 142GV, 144GV, 146GV, 148GV and 150GV, second to sixth lower signal vias 142SV, 144SV, 146SV, 148SV and 150SV, second to sixth metal vias 142MV, 144MV, 146MV, 148MV and 150MV, fourth to sixth upper ground layers 126G, 128G and 130G, fourth and fifth upper signal layers 126S and 128S, third to sixth upper insulating layers 125, 127, 129 and 131, second to fifth upper ground vias 122GV, 124GV, 126GV and 128GV and second to fourth upper signal vias 122SV, 124SV, and 126SV may be formed using the substantially same method as the method described with reference to FIG. 8.

Although not shown, an upper ground pad and an upper signal pad may be formed on an upper surface of the sixth upper insulating layer 131. The upper ground layers 120G, 122G, 124G, 126G, 128G and 130G and the upper ground vias 120GV, 122GV, 124GV, 126GV and 128GV may be electrically connected to the upper ground pad, and the upper signal layers 120S, 122S, 124S, 126S and 128S and the upper signal vias 120SV, 122SV, 124SV, and 126SV may be electrically connected to the upper signal pad.

A lower solder mask layer 160 may be formed on a lower surface 151L of the sixth lower insulating layer 151 (e.g., a lowermost insulating layer). The lower solder mask layer 160 may expose a lower surface of the seventh lower ground layer 152G (e.g., a lowermost ground layer) and a lower surface of the seventh lower signal layer 152S (e.g., a lowermost signal layer), and may cover the seventh metal layer 152M (e.g., a lowermost metal layer). Connection terminals 170 may be respectively formed on the exposed lower surfaces of the seventh lower ground layer 152G (e.g., the lowermost ground layer) and the seventh lower signal layer 152S (e.g., the lowermost signal layer). The seventh lower ground layer 152G (e.g., the lowermost ground layer) may be referred to as a lower ground pad, and a ground voltage may be applied to the lower ground layers 140G, 142G, 144G, 146G, 148G, 150G and 152G and the lower ground vias 140GV, 142GV, 144GV, 146GV, 148GV and 150GV through a connection terminal 170 on the lower ground pad 152G. The seventh lower signal layer 152S (e.g., the lowermost signal layer) may be referred to as a lower signal pad, and a signal voltage may be applied to the lower signal layers 140S, 142S, 144S, 146S, 148S, 150S and 152S and the lower signal vias 140SV, 142SV, 144SV, 146SV, 148SV and 150SV through a connection terminal 170 on the lower signal pad 152S.

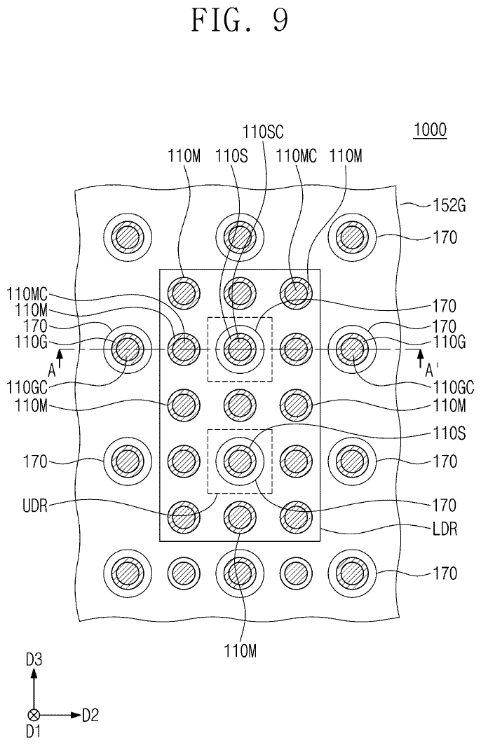

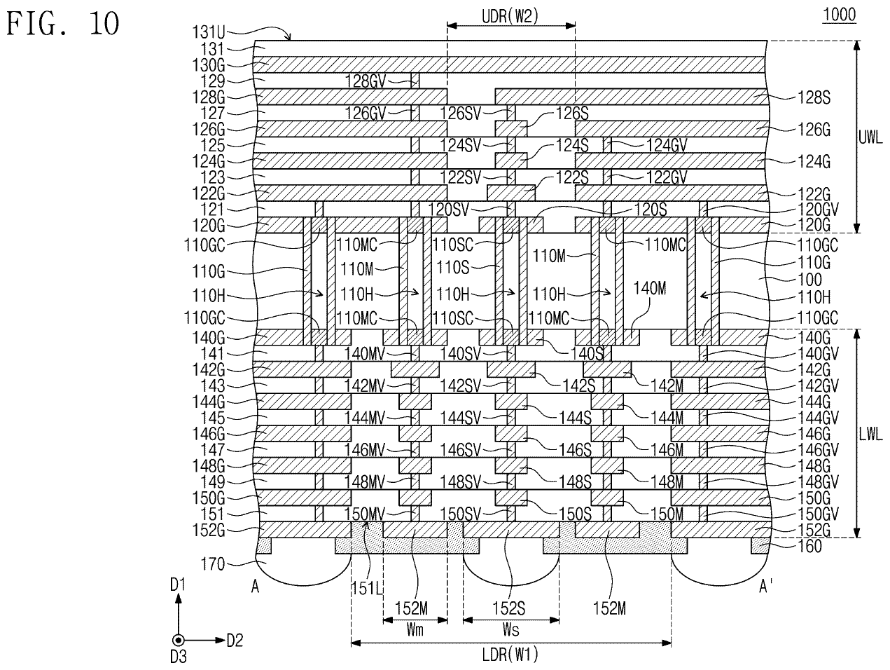

FIG. 9 is a plan view of a package substrate according to some embodiments of the present disclosure, and FIG. 10 is a cross-sectional view taken along A-A′ of FIG. 9. In order to simplify description, a difference from the package substrate described with reference to FIGS. 1 to 3 will be mainly described.

Referring to FIGS. 9 and 10, according to some embodiments, each of the penetration vias 110G, 110M and 110S may have an empty region 110H thereinside. Each of the penetration vias 110G, 110M and 110S may have end portions opposed to each other in the first direction D1, and the end portions of each of the penetration vias 110G, 110M and 110S may be filled with capping patterns 110GC, 110MC and 110SC. For example, the capping patterns 110GC, 110MC and 110SC may include a metal material such as copper (Cu) or tungsten (W).

The capping patterns 110GC, 110MC and 110SC may include ground capping patterns 110GC that fill both end portions of the ground penetration via 110G, metal capping patterns 110MC that fill both end portions of the metal penetration via 110M and signal capping patterns 110SC that fill both end portions of the signal penetration via 110S.

According to the present embodiments, since the end portions of each of the penetration vias 110G, 110M and 110S are filled with the capping patterns 110GC, 110MC and 110SC, degree of freedom in disposing the first lower ground via 140GV, the first metal via 140MV, the first lower signal via 140SV, the first upper ground via 120GV and the first upper signal via 120SV may increase.

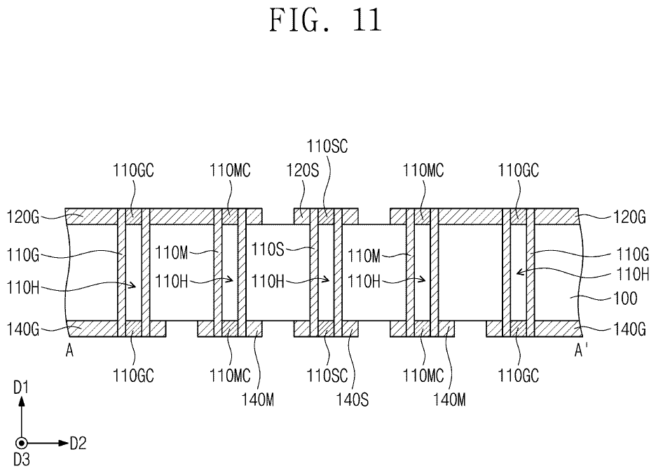

FIG. 11 is a diagram illustrating a method for manufacturing a package substrate according to some embodiments of the present disclosure, and is a cross-sectional view corresponding to A-A′ of FIG. 9. In order to simplify description, a difference from the method for manufacturing a package substrate described with reference to FIGS. 4 to 8 will be mainly described.

First, as described with reference to FIGS. 4 to 6, the first lower conductive layer 140 may be formed on a lower surface 100L of the core layer 100, and the first upper conductive layer 120 may be formed on an upper surface 100U of the core layer 100. The first lower ground layer 140G, the first metal layer 140M and the first lower signal layer 140S may be formed by patterning the first lower conductive layer 140. The first upper ground layer 120G and the first upper signal layer 120S may be formed by patterning the first upper conductive layer 120. The penetration via holes 110GH, 110MH and 110SH penetrating the core layer 100 may be formed.

Referring to FIG. 11, penetration vias 110G, 110M and 110S may be respectively formed in the penetration via holes 110GH, 110MH and 110SH. For example, forming the penetration vias 110G, 110M and 110S may include forming a penetration via conductive layer conformally covering inner surfaces of the penetration via holes 110GH, 110MH and 110SH. Accordingly, each of the penetration vias 110G, 110M and 110S may be formed so as to have a hollow cylinder shape having an empty region 110H thereinside. The penetration vias 110G, 110M and 110S may include a ground penetration via 110G formed in the ground penetration via hole 110GH, and connected to the first lower ground layer 140G and the first upper ground layer 120G, a metal penetration via 110M formed in the metal penetration via hole 110MH, and connected to the first metal layer 140M and the first upper ground layer 120G, and a signal penetration via 110S formed in the signal penetration via hole 110SH, and connected to the first lower signal layer 140S and the first upper signal layer 120S.

Each of the penetration vias 110G, 110M and 110S may have end portions opposed to each other in the first direction D1, and capping patterns 110GC, 110MC and 110SC may be formed so as to fill the end portions of each of the penetration vias 110G, 110M and 110S. For example, the capping patterns 110GC, 110MC and 110SC may be formed using chemical vapor deposition, physical vapor deposition, or an electroplating method. The capping patterns 110GC, 110MC and 110SC may include ground capping patterns 110GC that fill both end portions of the ground penetration via 110G, metal capping patterns 110MC that fill both end portions of the metal penetration via 110M and signal capping patterns 110SC that fill both end portions of the signal penetration via 110S.

A process thereafter is substantially the same as the method for manufacturing a package substrate described with reference to FIGS. 7 to 8.

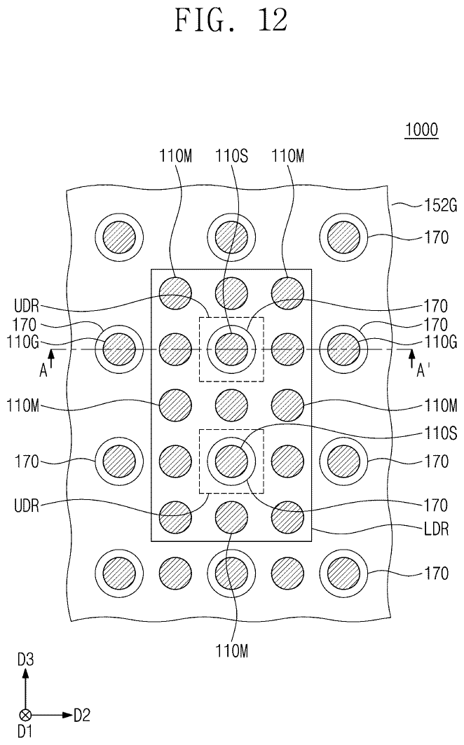

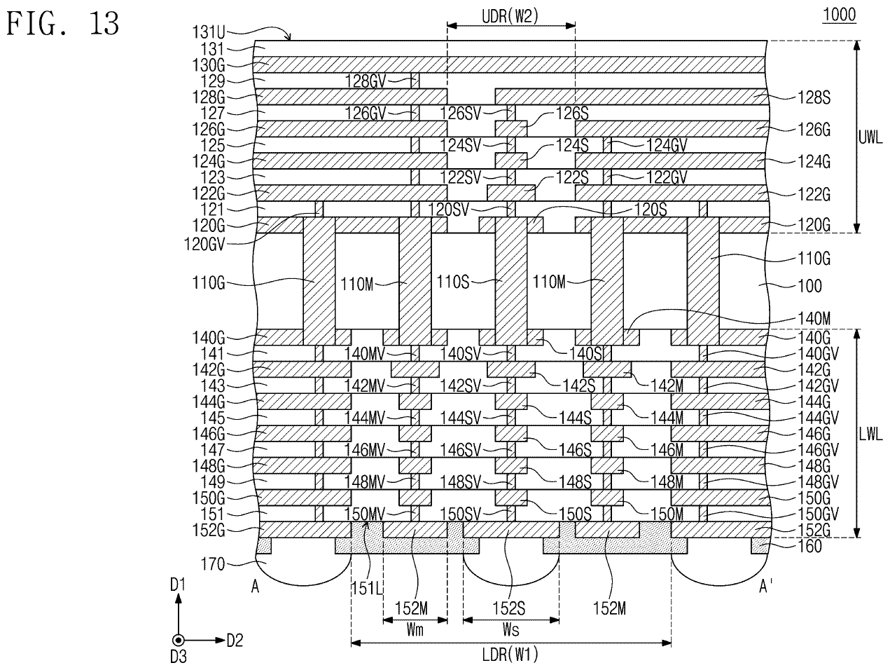

FIG. 12 is a plan view of a package substrate according to some embodiments of the present disclosure, and FIG. 13 is a cross-sectional view taken along A-A′ of FIG. 12. In order to simplify description, a difference from the package substrate described with reference to FIGS. 1 to 3 will be mainly described.

Referring to FIGS. 12 and 13, according to some embodiments, each of the penetration vias 110G, 110M and 110S may have a pillar shape penetrating the core layer 100, and insides thereof may be filled with a conductive material. That is, each of the penetration vias 110G, 110M and 110S may not have an empty region thereinside.

According to the present embodiments, since each of the penetration vias 110G, 110M and 110S has a pillar shape, degree of freedom in disposing the first lower ground via 140GV, the first metal via 140MV, the first lower signal via 140SV, the first upper ground via 120GV and the first upper signal via 120SV may increase.

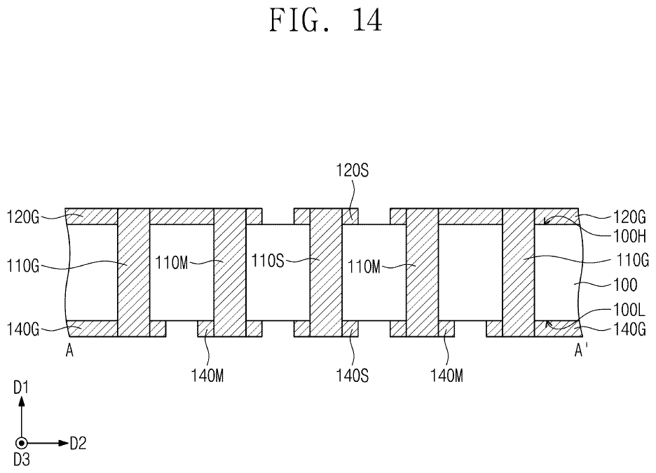

FIG. 14 is a diagram illustrating a method for manufacturing a package substrate according to some embodiments of the present disclosure, and is a cross-sectional view corresponding to A-A′ of FIG. 12. In order to simplify description, a difference from the method for manufacturing a package substrate described with reference to FIGS. 4 to 8 will be mainly described.

First, as described with reference to FIGS. 4 to 6, the first lower conductive layer 140 may be formed on a lower surface 100L of the core layer 100, and the first upper conductive layer 120 may be formed on an upper surface 100U of the core layer 100. The first lower ground layer 140G, the first metal layer 140M and the first lower signal layer 140S may be formed by patterning the first lower conductive layer 140. The first upper ground layer 120G and the first upper signal layer 120S may be formed by patterning the first upper conductive layer 120. The penetration via holes 110GH, 110MH and 110SH penetrating the core layer 100 may be formed.

Referring to FIG. 14, penetration vias 110G, 110M and 110S may be respectively formed in the penetration via holes 110GH, 110MH and 110SH. According to some embodiments, forming the penetration vias 110G, 110M and 110S may include forming a penetration via conductive layer that fills the penetration via holes 110GH, 110MH and 110SH. Accordingly, each of the penetration vias 110G, 110M and 110S may be formed so as to have a shape of a pillar extending in the first direction D1. The penetration vias 110G, 110M and 110S may include a ground penetration via 110G formed in the ground penetration via hole 110GH, and connected to the first lower ground layer 140G and the first upper ground layer 120G, a metal penetration via 110M formed in the metal penetration via hole 110MH, and connected to the first metal layer 140M and the first upper ground layer 120G, and a signal penetration via 110S formed in the signal penetration via hole 110SH, and connected to the first lower signal layer 140S and the first upper signal layer 120S.

A process thereafter is substantially the same as the method for manufacturing a package substrate described with reference to FIGS. 7 to 8.

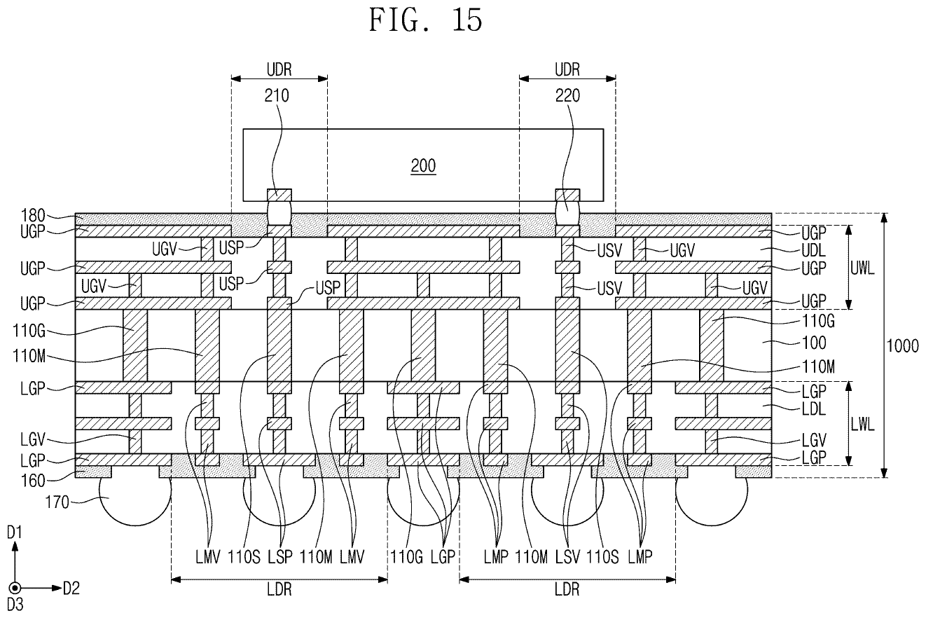

FIG. 15 is a cross-sectional view of a semiconductor package according to some embodiments of the present disclosure.

Referring to FIG. 15, the semiconductor package may include a package substrate 1000 and a semiconductor chip 200 mounted on the package substrate 1000. The package substrate 1000 may be configured so as to be substantially identical to the package substrate 1000 described with reference to FIGS. 1 to 14.

The package substrate 1000 may include the lower wiring layer LWL, the upper wiring layer UWL on the lower wiring layer LWL and the core layer 100 between the lower wiring layer LWL and the upper wiring layer UWL.

The lower wiring layer LWL may include a plurality of lower ground layers LGP spaced apart from each other in the first direction D1, lower ground vias LGV between the lower ground layers LGP, a plurality of lower signal layers LSP spaced apart from each other in the first direction D1, lower signal vias LSV between the lower signal layers LSP, a plurality of metal layers LMP spaced apart from each other in the first direction D1, metal vias LMV between the metal layers LMP and a lower insulating layer LDL.

The lower ground layers LGP and the lower ground vias LGV may correspond to the lower ground layers 140G, 142G, 144G, 146G, 148G, 150G and 152G and the lower ground vias 140GV, 142GV, 144GV, 146GV, 148GV and 150GV described with reference to FIGS. 1 to 14. The lower signal layers LSP and the lower signal vias LSV may correspond to the lower signal layers 140S, 142S, 144S, 146S, 148S, 150S and 152S and the lower signal vias 140SV, 142SV, 144SV, 146SV, 148SV and 150SV described with reference to FIGS. 1 to 14. The metal layers LMP and the metal vias LMV may correspond to the metal layers 140M, 142M, 144M, 146M, 148M, 150M and 152M and the metal vias 140MV, 142MV, 144MV, 146MV, 148MV, 150MV and 152MV described with reference to FIGS. 1 to 14. The lower insulating layer LDL may correspond to the lower insulating layers 141, 143, 145, 147, 149 and 151 described with reference to FIGS. 1 to 14.

The lower wiring layer LWL may include a lower insulating region LDR extending in the first direction D1 to penetrate the lower ground layers LGP. The lower insulating region LDR is substantially the same as the lower insulating region LDR described with reference to FIGS. 1 to 14. The lower signal layers LSP and the lower signal vias LSV may be disposed in the lower insulating region LDR, and may be horizontally (e.g., in the second direction D2) spaced apart from the lower ground layers LGP and the lower ground vias LGV. The metal layers LMP and the metal vias LMV may be disposed in the lower insulating region LDR, and may be horizontally (e.g., in the second direction D2) spaced apart from the lower ground layers LGP and the lower ground vias LGV.

The lower signal layers LSP and the lower signal vias LSV may be referred to as a lower signal group LSP and LSV, the metal layers LMP and the metal vias LMV may be referred to as a metal pattern group LMP and LMV, and the lower ground layers LGP and lower ground vias LGV may be referred to as a lower ground group LGP and LGV. The lower signal group LSP and LSV and the metal pattern group LMP and LMV may be disposed in the lower insulating region LDR, and may be horizontally (e.g., in the second direction D2) spaced apart from each other. The metal pattern group LMP and LMV may be disposed between the lower signal group LSP and LSV and the lower ground group LGP and LGV, and may be horizontally (e.g., in the second direction D2) spaced apart from the lower ground group LGP and LGV.

The package substrate 1000 may further include the penetration vias 110G, 110M and 110S penetrating the core layer 100. The lower ground group LGP and LGV may be electrically connected to the ground penetration via 110G among the penetration vias 110G, 110M and 110S. The metal pattern group LMP and LMV may be electrically connected to the metal penetration via 110M among the penetration vias 110G, 110M and 110S. The lower signal group LSP and LSV may be electrically connected to the signal penetration via 110S among the penetration vias 110G, 110M and 110S.

The package substrate 1000 may further include the lower solder mask layer 160 disposed on a lower surface of the lower wiring layer LWL. The lower solder mask layer 160 may expose a lower surface of a lowermost ground layer LGP among the lower ground layers LGP, and may expose a lower surface of a lowermost signal layer LSP among the lower signal layers LSP. The lower solder mask layer 160 may cover a lower surface of a lowermost metal layer LMP among the metal layers LMP. The lowermost ground layer LGP and the lowermost signal layer LSP may be respectively referred to as a lower ground pad and a lower signal pad. The package substrate 1000 may further include the connection terminals 170 respectively disposed on the exposed lower surfaces of the lowermost signal layer LSP and the lowermost ground layer LGP.

The upper wiring layer UWL may include a plurality of upper ground layers UGP spaced apart from each other in the first direction D1, upper ground vias UGV between the upper ground layers UGP, a plurality of upper signal layers USP spaced apart from each other in the first direction D1, upper signal vias USV between the upper signal layers USP and an upper insulating layer UDL. The upper ground layers UGP and the upper ground vias UGV may correspond to the upper ground layers 120G, 122G, 124G, 126G, 128G and 130G and the upper ground vias 120GV, 122GV, 124GV, 126GV and 128GV described with reference to FIGS. 1 to 14. The upper signal layers USP and the upper signal vias USV may correspond to the upper signal layers 120S, 122S, 124S, 126S and 128S and the upper signal vias 120SV, 122SV, 124SV, and 126SV described with reference to FIGS. 1 to 14. The upper insulating layer UDL may correspond to the upper insulating layers 121, 123, 125, 127, 129 and 131 described with reference to FIGS. 1 to 14.

The upper wiring layer UWL may include an upper insulating region UDR extending in the first direction D1 to penetrate the upper ground layers UGP. The upper insulating region UDR is substantially the same as the upper insulating region UDR described with reference to FIGS. 1 to 14. The upper signal layers USP and the upper signal vias USV may be disposed in the upper insulating region UDR, and may be horizontally (e.g., in the second direction D2) spaced apart from the upper ground layers UGP and the upper ground vias UGV.

The upper signal layers USP and the upper signal vias USV may be electrically connected to the signal penetration via 110S, and may be electrically connected to the lower signal layers LSP and the lower signal vias LSV through the signal penetration via 110S. The upper ground layers UGP and the upper ground vias UGV may be electrically connected to the ground penetration via 110G and the metal penetration via 110M. Accordingly, the metal layers LMP and the metal vias LMV may be electrically connected to the upper ground layers UGP and the upper ground vias UGV through the metal penetration via 110M, and the lower ground layers LGP and the lower ground vias LGV may be electrically connected to the upper ground layers UGP and the upper ground vias UGV through the ground penetration via 110G.

The package substrate 1000 may further include an upper solder mask layer 180 disposed on an upper surface of the upper wiring layer UWL. Although not shown, the upper solder mask layer 180 may expose an upper surface of the uppermost ground layer UGP among the upper ground layers UGP, and may expose an upper surface of the uppermost signal layer USP among the upper signal layers USP. The uppermost ground layer UGP and the uppermost signal layer USP may be respectively referred to as an upper ground pad and an upper signal pad. For example, the upper solder mask layer 180 may be a solder mask or solder resist, and may include an insulating material.

The semiconductor chip 200 may include integrated circuits, and the integrated circuits may include, for example, a memory circuit, a logic circuit or a combination thereof. The semiconductor chip 200 may include chip pads 210 disposed on a lower surface thereof and chip connection terminals 220 respectively disposed on the chip pads 210. The chip pads 210 may include a conductive material, and may include, for example, metal. The chip pads 210 may be electrically connected to the integrated circuits of the semiconductor chip 200. The chip connection terminals 220 may include a conductive material, and may have at least one shape of a solder ball, a bump or a pillar. The chip connection terminals 220 may be electrically connected to the integrated circuits of the semiconductor chip 200 through the chip pads 210.

The semiconductor chip 200 may be electrically connected to the upper wiring layer UWL of the package substrate 1000. The chip connection terminals 220 of the semiconductor chip 200 may be disposed on the upper ground pad and the upper signal pad (e.g., the uppermost ground layer UGP and the uppermost signal layer USP). The semiconductor chip 200 may be electrically connected to the package substrate 1000 through the chip pads 210, the chip connection terminals 220, the upper ground pad UGP and the upper signal pad USP (e.g., the uppermost ground layer UGP and the uppermost signal layer USP).

According to the present disclosure, a lower wiring layer of a package substrate may include lower ground layers stacked in a vertical direction, a lower insulating region extending in the vertical direction to penetrate the lower ground layers, a lower signal group disposed in the lower insulating region, and a metal pattern group disposed in the lower insulating region, and disposed between the lower ground layers and the lower signal group. The lower signal group may be spaced, by a horizontally required distance, apart from the lower ground layers and the metal pattern group, and thus parasitic capacitance therebetween may be reduced. As a result, impedance characteristics of a signal applied to the lower signal group may be improved.

In addition, since the metal pattern group is disposed in the lower insulating region between the lower signal group and the lower ground layers, breaking lower insulating layers in the lower insulating region may be suppressed.

Accordingly, the package substrate with improved electrical characteristics and reliability, and a semiconductor package including the same may be provided.

The above description of embodiments of the present disclosure provides an example for description of the present disclosure. Therefore, the present disclosure is not limited to the above embodiments, and it is obvious that various modifications and changes such as combining the above embodiments may be made by those skilled in the art within the technical spirit of the present disclosure.

What is claimed is:

1. A package substrate comprising:
a first wiring layer; and
a second wiring layer on the first wiring layer,
wherein the first wiring layer comprises:
a plurality of first ground layers spaced apart from each other in a first direction perpendicular to a first surface of the first wiring layer;
a plurality of first signal layers spaced apart from each other in the first direction, and spaced apart from the plurality of first ground layers along a second direction parallel to the first surface of the first wiring layer;
a plurality of metal layers spaced apart from each other in the first direction between the plurality of first ground layers and the plurality of first signal layers, and spaced apart from the plurality of first ground layers and the plurality of first signal layers along the second direction; and
a plurality of first insulating layers between the plurality of first ground layers, and extending between the plurality of metal layers, and between the plurality of first signal layers, and
wherein the first surface of the first wiring layer is a surface of an insulating layer among the plurality of first insulating layers.

2. The package substrate of claim 1, wherein the plurality of metal layers are separated from the plurality of first ground layers and the plurality of first signal layers by the plurality of first insulating layers.

3. The package substrate of claim 2, further comprising a first solder mask layer on the first surface of the first wiring layer,
wherein the first solder mask layer does not cover a first surface of a ground layer among the plurality of first ground layers, does not cover a first surface of a signal layer among the plurality of first signal layers, and covers a metal layer among the plurality of metal layers.

4. The package substrate of claim 3, further comprising connection terminals on the first surface of the ground layer and the first surface of the signal layer not covered by the first solder mask layer.

5. The package substrate of claim 1, wherein the first wiring layer further comprises:
first ground vias respectively between the plurality of first ground layers, and in the plurality of first insulating layers, and connecting the plurality of first ground layers;
first signal vias respectively between the plurality of first signal layers, and in the plurality of first insulating layers, and connecting the plurality of first signal layers; and
metal vias respectively between the plurality of metal layers, and in the plurality of first insulating layers, and connecting the plurality of metal layers.

6. The package substrate of claim 5, wherein the plurality of metal layers and the metal vias are separated from the plurality of first ground layers and the first ground vias by the plurality of first insulating layers, and
the plurality of first signal layers and the first signal vias are separated from the plurality of metal layers and the metal vias by the plurality of first insulating layers.

7. The package substrate of claim 1, wherein the second wiring layer comprises:
a plurality of second ground layers spaced apart from each other in the first direction;
a plurality of second signal layers spaced apart from each other in the first direction, and spaced apart from the plurality of second ground layers along the second direction; and
a plurality of second insulating layers between the plurality of second ground layers, and extending between the plurality of second signal layers,
the plurality of first ground layers and the plurality of metal layers are connected to the plurality of second ground layers, and
the plurality of first signal layers are connected to the plurality of second signal layers.

8. The package substrate of claim 7, further comprising:
a core layer between the first wiring layer and the second wiring layer; and
a plurality of penetration vias penetrating the core layer and spaced apart from each other in the second direction,
wherein the plurality of first ground layers are connected to the plurality of second ground layers through a ground penetration via among the plurality of penetration vias,
the plurality of metal layers are connected to the plurality of second ground layers through a metal penetration via among the plurality of penetration vias, and
the plurality of first signal layers are connected to the plurality of second signal layers through a signal penetration via among the plurality of penetration vias.

9. The package substrate of claim 1, further comprising:
a core layer between the first wiring layer and the second wiring layer; and
a plurality of penetration vias penetrating the core layer and spaced apart from each other in the second direction,
wherein the plurality of penetration vias comprise:
a ground penetration via connected to the plurality of first ground layers;
a signal penetration via connected to the plurality of first signal layers, and spaced apart from the ground penetration via along the second direction; and
a metal penetration via connected to the plurality of metal layers, and between the ground penetration via and the signal penetration via.

10. The package substrate of claim 9, wherein each of the plurality of penetration vias has a pillar shape penetrating the core layer along the first direction.

11. The package substrate of claim 9, wherein each of the plurality of penetration vias has a hollow cylinder shape penetrating the core layer along the first direction.

12. The package substrate of claim 9, wherein the second wiring layer comprises:
a plurality of second ground layers spaced apart from each other in the first direction;
a plurality of second signal layers spaced apart from each other in the first direction, and spaced apart from the plurality of second ground layers along the second direction; and
a plurality of second insulating layers between the plurality of second ground layers, and extending between the plurality of second signal layers,
the ground penetration via and the metal penetration via are connected to the plurality of second ground layers, and
the signal penetration via is electrically connected to the plurality of second signal layers.

13. The package substrate of claim 12, wherein the plurality of second signal layers are separated from the plurality of first ground layers by the plurality of second insulating layers.

14. A package substrate comprising:
a first wiring layer and a second wiring layer stacked along a first direction,
wherein the first wiring layer comprises:
a plurality of first ground layers spaced apart from each other in the first direction;
a first insulating region penetrating the plurality of first ground layers and extending in the first direction;
a plurality of first signal layers in the first insulating region, and spaced apart from each other in the first direction; and
a plurality of metal layers in the first insulating region, and between the plurality of first ground layers and the plurality of first signal layers, and spaced apart from each other in the first direction, and
wherein the second wiring layer comprises:
a plurality of second ground layers spaced apart from each other in the first direction;
a second insulating region penetrating the plurality of second ground layers, and extending in the first direction; and
a plurality of second signal layers in the second insulating region, and spaced apart from each other in the first direction,
wherein the plurality of first ground layers and the plurality of metal layers are electrically connected to the second ground layers, and
wherein the plurality of first signal layers are electrically connected to the plurality of second signal layers.

15. The package substrate of claim 14, wherein a width along a second direction of the first insulating region is greater than a width along the second direction of the second insulating region, and
the second direction is parallel to a first surface of the first wiring layer.

16. The package substrate of claim 14, wherein a width along a second direction of the first insulating region is greater than a maximum width along the second direction of the plurality of first signal layers, and
the second direction is parallel to a first surface of the first wiring layer.

17. The package substrate of claim 16, wherein the width along the second direction of the first insulating region is greater than a sum of the maximum width along the second direction of the plurality of first signal layers and a maximum width along the second direction of the plurality of metal layers.

18. The package substrate of claim 14, wherein the plurality of metal layers are spaced apart from the plurality of first ground layers and the plurality of first signal layers in a second direction, and
the second direction is parallel to a first surface of the first wiring layer.

19. The package substrate of claim 14, wherein the plurality of first signal layers are separated from the plurality of metal layers by the first insulating region, and
the plurality of metal layers are separated from the plurality of first ground layers by the first insulating region.

20. The package substrate of claim 19, wherein the plurality of second signal layers are separated from the plurality of second ground layers by the second insulating region.
